(19) United States
(12) Patent Application Publication
(10) Pub. No.: US 2018/0110150 A1
(43) Pub. Date: Apr. 19, 2018

(54) SCALABLE ELECTRIC PROVISIONING SYSTEM

(71) Applicants: Pierre BLANCHET, MONTREAL (CA); Handy FORTIN-BLANCHETTE, MONTREAL (CA)

(72) Inventors: Pierre BLANCHET, MONTREAL (CA); Handy FORTIN-BLANCHETTE, MONTREAL (CA)

(21) Appl. No.: 15/783,312

(22) Filed: Oct. 13, 2017

Related U.S. Application Data
(60) Provisional application No. 62/408,683, filed on Oct. 14, 2016.

(51) Int. Cl. H05K 7/14; H02J 3/38; H02J 7/00; H05K 5/00; H05K 7/02

(52) U.S. Cl. CPC H05K 7/1457; H02J 3/383; B60L 11/1816; H05K 5/0017; H05K 7/023; H02J 7/0052

(57) ABSTRACT

The present disclosure relates to a scalable electric provisioning system comprising a housing, a high voltage direct current (DC) backplane, a communication bus, at least one provisioning module and a control unit. The housing defines a plurality of slots. The high voltage direct current (DC) backplane is located within the housing and is electrically accessible through each one of the plurality of slots. The communication bus is accessible to each one of the plurality of slots. The at least one provisioning module is inserted into one of the slots. The at least one provisioning module comprises two sub-units selected from any of the following: a DC/DC converter, a DC/DC bidirectional converter, an electric inverter, and a bidirectional electric inverter. The control unit controls operation of the at least one provisioning unit.

### TECHNICAL FIELD

The present disclosure relates to the field of electric systems, and more particularly to the provisioning of Direct Current (DC) and Alternating Current (AC) coming from to various electrical equipments.

### BACKGROUND

The demand for power converters in the field of renewable energy to interact with sources, storage units (such as batteries) and alternative current electrical loads as the utility grid or a micro-grid or isolated grid is growing quickly. The key to business success is undoubtedly the final price of theses converters for the consumer, the stability of the system and the communication features.

The easiest way to achieve this goal is the reduction of component count, without sacrificing quality. The industry trend, with the arrival of new types of transistors such as Silicon Carbide MOSFET (SiCMOS) or Gallium Nitride (GaN), is to increase the switching frequency and reduce the size of passives components. However, the strong voltage slopes generated across these new semiconductor devices generate potential noise which propagates in the control board supply causing spurious behavior.

Another market trend is to improve the information sharing between distributed small power producers and the utility grid management system for optimal distribution of energy resources and potential revenues opportunities. The management system could use inverters from a given residential network to contribute to grid stability by the implementation of advanced functions, data exchange and orders to be executed to correct or improve the power quality. This involves a local advanced unit that is upgradable over time as the utility needs will evolve. This unit must maintain the stability of the local network as well.

There is therefore a need for a system with reduced components count. There is further a need for a system that provides an almost infinite and safe expansion of electrical provisioning from varied sources while allowing evolution through time.

### SUMMARY

A scalable electric provisioning system comprising a housing, a high voltage direct current (DC) backplane, a communication interface, at least one provisioning module and a control unit. The housing defines a plurality of slots. The high voltage direct current (DC) backplane is located within the housing and is electrically accessible through each one of the plurality of slots. The at least one provisioning module is inserted into one of the slots. The at least one provisioning module comprises two sub-units selected from any of the following: a DC/DC converter, a DC/DC bidirectional converter, an electric inverter, and a bidirectional electric inverter. The two sub-units are directly electrically connected to the high voltage DC backplane. The control unit controls operation of the at least one provisioning unit. The control unit generate control messages comprising operating parameters for the at least one provisioning unit. The control messages are delivered through the communication interface.

### BRIEF DESCRIPTION OF THE DRAWINGS

Embodiments of the disclosure will be described by way of example only with reference to the accompanying drawings, in which:

FIG. 1 is a partial schematic of an example of a scalable electric power provisioning system;

FIGS. 2A-2E depict various exemplary functional configurations of the present electric provisioning system 100;

FIG. 3 is a schematic of a provisioning module 106;

FIG. 4 is a partial circuit showing an example of two electric transforming units of a provisioning module 106, in which the electric transforming units are two DC/DC bidirectional converter 302 and 304;

FIG. 5 illustrates a circuit showing an example of two electric transforming units of a provisioning module 106, in which the electric transforming units are one DC/DC bidirectional converter 120A and one dual DC/DC bidirectional converter 120B;

FIG. 6 illustrates yet another circuit showing an example of two electric transforming units of a provisioning module 106, in which the electric transforming units are a dual DC/DC bidirectional converter 120, and two dual DC/DC bidirectional converters 125; and

FIG. 7 illustrates yet another circuit showing an example of two electric transforming units of a provisioning module 106, in which the electric transforming units are a DC/DC converter 120 and a DC/AC bidirectional inverter 130.

### DETAILED DESCRIPTION

The foregoing and other features will become more apparent upon reading of the following non-restrictive description of illustrative embodiments thereof, given by way of example only with reference to the accompanying drawings. Like numerals represent like features on the various drawings.

Throughout the present specification, the expression “electrical equipment” is used to refer to any device or network with which the present electric provisioning system 100 may interact, and includes without restriction, the following examples of electrical equipment: one or several solar panel, one or several wind generator, a gas generator, one or several hydraulic generator, a utility grid, a local electric network, one or several car battery chargers, a residential electrical distribution system, one or several batteries, an energy storage device, etc.

The present disclosure relates to a scalable electric provisioning system 100. The scalable electric provisioning system 100 is designed to be used with any combination of electrical equipment, including: grid, off grid, renewable energy source, battery, generator, car charger, residential distribution system, etc. The scalability of the electric provisioning system 100 lies in its robust and flexible architecture.

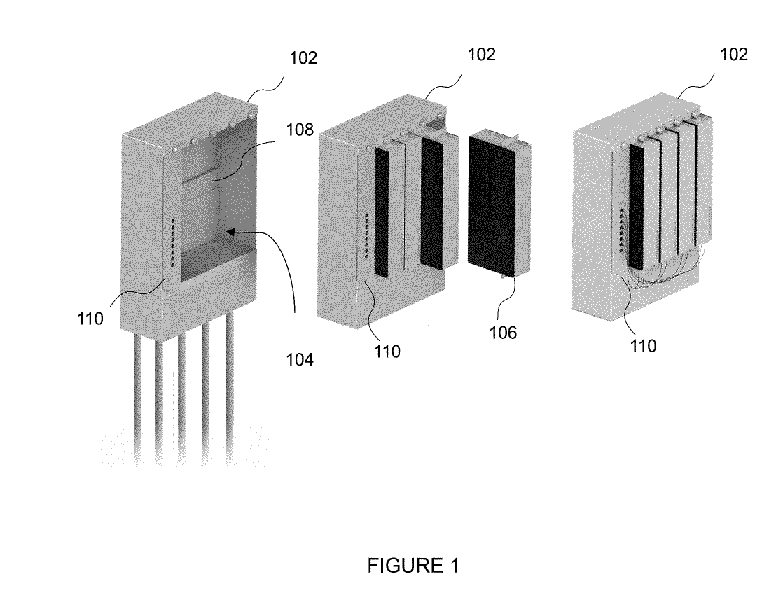

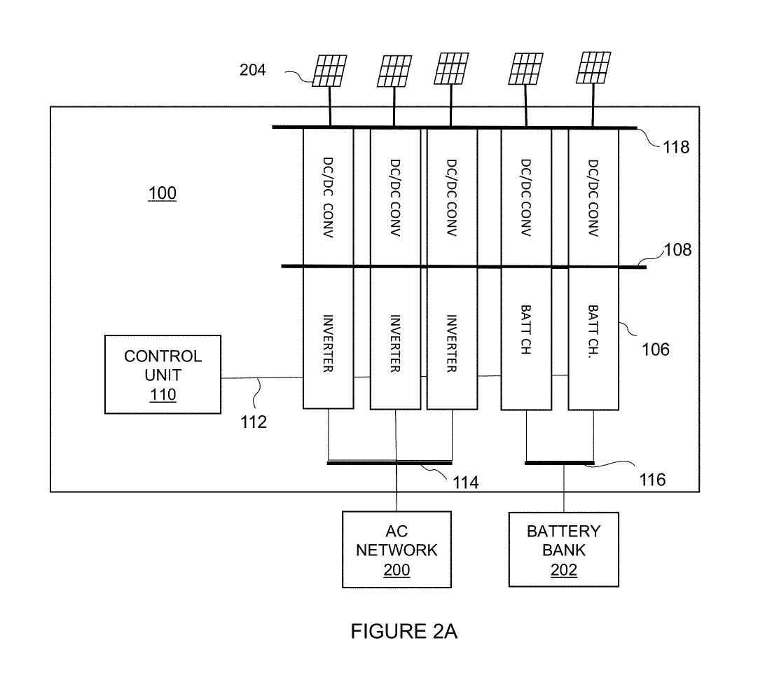

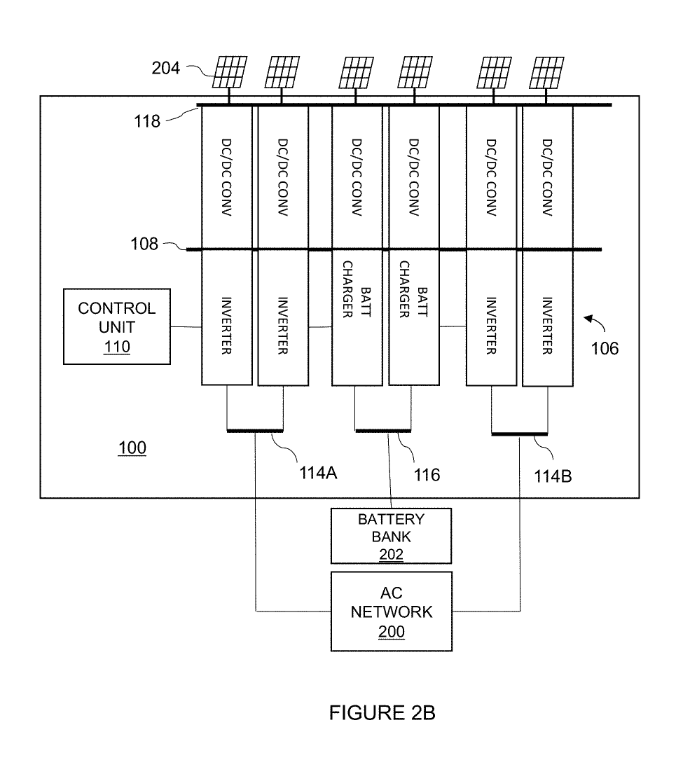

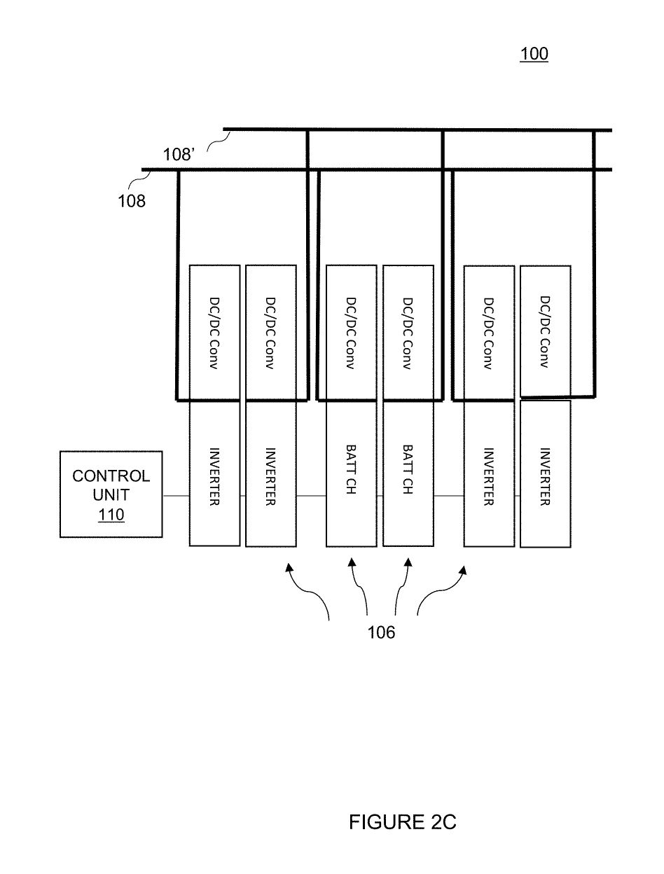

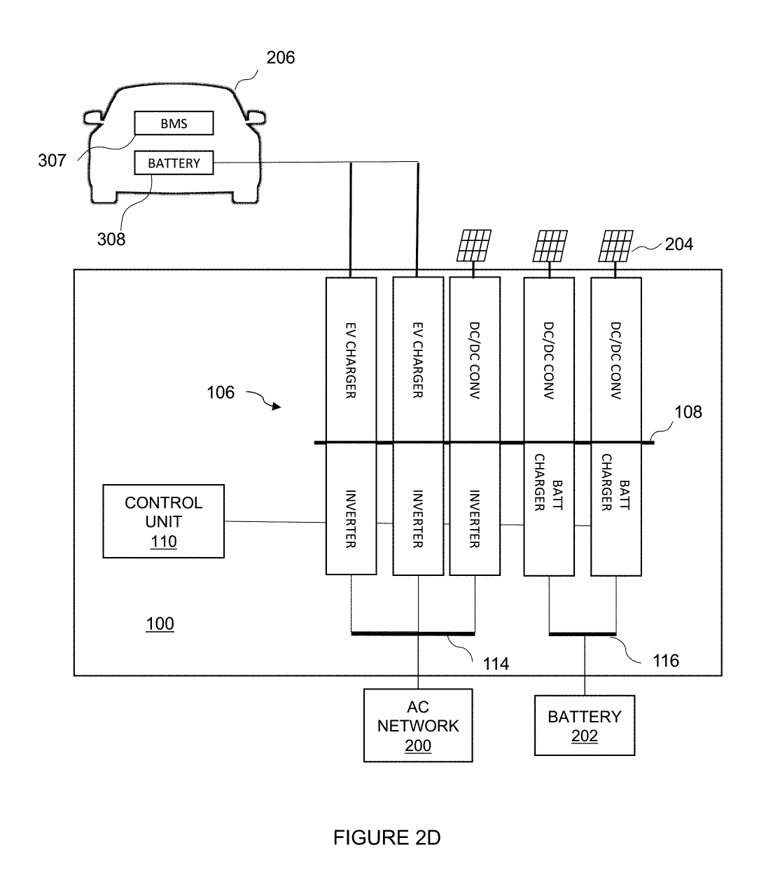

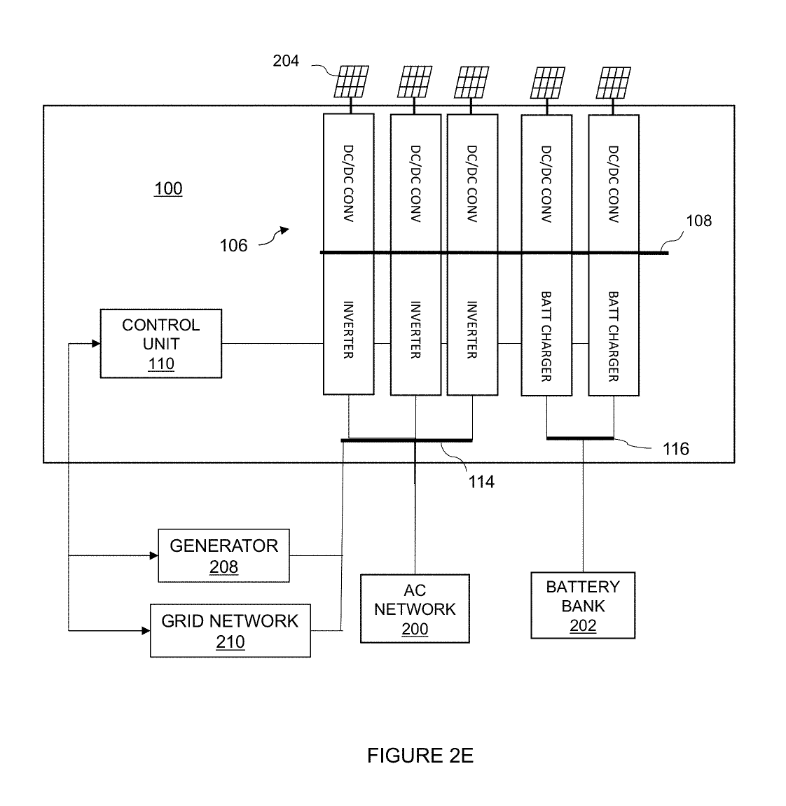

Reference is now concurrently made to FIG. 1 and FIGS. 2A-2E. Although shown as distinct examples, FIGS. 2A-2E illustrate various examples of configurations of the electric provisioning system 100. The configurations illustrated in FIGS. 2A-2E should not be construed as different embodiments of the present electric provisioning system 100, but rather as simplified functional diagrams, assisting at introducing various elements of the present electric provisioning system 100.

The electric provisioning system 100 comprises a housing 102 made of any material that is commonly used for electric supply equipment. The housing 102 comprises a plurality of slots 104. Each slot 104 is sized and adapted to receive a provisioning module 106, which will be discussed further. The housing 102 further comprises a high voltage direct current (DC) backplane 108 (for example 230V). The high voltage DC backplane 108 is located within the housing 102 and is electrically accessible through the plurality of slots 104. The high voltage DC backplane 108 directly exchanges electricity with the provisioning modules 106 upon electric contact therewith. The high voltage DC backplane 108 allows high voltage DC electric power exchange between the provisioning modules 106 connected thereto, and creates an internal electric network within the electric provisioning system 100. The internal electric network created by the provisioning modules 106 connected to the high voltage DC backplane 108 stabilizes the high voltage DC electricity exchanged thereon.

In addition to the high voltage DC backplane 108, the electric provisioning system 100 further comprises distinct sub-network electric planes. More particularly, to support flexibility and scalability, the electric provisioning system 100 may further comprise an AC sub-network electric plane 114, a DC sub-network electric plane 116, and a renewable energy sub-network electric plane 118. The AC sub-network electric plane 114 may be connected to one or several electrical equipments with AC electrical requirements. The DC sub-network electric plane 116 may be connected to one or several electrical equipments with DC electrical requirements corresponding to the DC sub-network electric plane electrical characteristics (current, voltage). The renewable energy sub-network electric plane 118 may be connected to one or several sources of renewable energy sharing similar electrical requirements. Furthermore, depending on the electric requirements of the electrical equipments connected thereto, the electric provisioning system 100 may comprise two AC sub-network electric planes 114A and 114B, as illustrated for example purposes on FIG. 2B. The AC sub-network electric planes 114A and 114B form first and second split phase outputs. The AC sub-network electric planes 114A and 114B form the split phase outputs while sharing a neutral line, thus providing two distinct AC phases to the AC network 200.

The electrical equipments are connected to the provisioning modules 106 either directly or through the sub-network electric planes 114, 116 or 118 corresponding to their electric input or output requirements (i.e. voltage and current requirements). The sub-network electric planes are not specifically shown on FIG. 1 for simplicity purposes, but those skilled in the art will understand that multiple sub-network electric planes may be physically contiguously provided in the housing 102, where each sub-network electric plane may be accessed for example by means of a connector such as a pin or combination of pins on the back of the provisioning modules 106. Also, as known in the art, the sub-network electric planes are electrically insulated from one another.

The current configuration of backplanes and slots 104 makes installation and modifications to the configuration of the electric provisioning system 100 simple, as provisioning modules 106 and control unit 108 can be inserted and removed with ease to obtain an electric provisioning solution adaptable to any electric power requirements configuration. Although not shown, the housing 102 further contains electrical protections such as electrical insulator, relays and breakers, to connect with the various electrical equipments while meeting the established electrical security standards and protecting users and electrical equipments connected thereto. The housing 102 also contains engagement and securing mechanisms to prevent the disengagement of the control unit 110 or one of the provisioning modules 106 by inadvertence.

The provisioning modules 106 can be disconnected easily when deactivated, or as hot pluggable and/or as hot swappable and removed for maintenance, repair or replacement, and put back easily by any user without requiring the intervention of a specialist or an electrician, thus reducing the overall cost of maintenance.

The electric provisioning system 100 receives at least one provisioning module 106 inserted in one of the slots 104 of the housing 102 for electrical connection with the high voltage DC backplane 108. Each provisioning module 106 comprises at least two electric transforming units selected from the following: a DC/DC converter, a buck-boost converter with Maximum Power Point Tracking (MPPT) algorithm, a DC/DC buck converter with MPPT algorithm, a boost DC/DC converter with MPPT algorithm, a DC/DC bidirectional converter, a DC/AC bidirectional inverter, a three phase AC/DC converter and a DC/DC bidirectional converter battery charger. Each of the two electric transforming units of each provisioning module 106 may be directly electrically connected to the high voltage DC backplane 108 by means of connecting pins provided on a back of each provisioning module 106.

FIGS. 2A-2E illustrate various combinations of electric transforming units in the provisioning modules 106 and connection of the electric provisioning system 100 to various examples of electrical equipments. For example, FIG. 2A illustrates the electric provisioning system 100 connected to the following electrical equipments: five solar panel arrays 204, to an AC network 200 and to a battery bank 202. In FIG. 2A, the electric provisioning system 100 comprises five provisioning modules 106, where the electric transformation units of three provisioning modules 106 are composed of DC/AC bidirectional inverter and DC/DC buck-boost converter, while the electric transformation units of two of the provisioning modules 106 are composed of DC/DC buck-boost converters and DC/DC bidirectional converter battery chargers.

In FIG. 2B, the electric provisioning system 100 is connected to the following electrical equipments: the AC network 200, the battery bank 202 and the solar panels 204 either directly or through the corresponding sub-network electric planes 114A, 114B, 116 and 118. Alternatively, some of the electrical equipments, such as for example each solar panel array 204 could be independently connected directly instead of being connected through the corresponding sub-network electric plane 118. The electric provisioning system 100 illustrated on FIG. 2B comprises six provisioning modules 106, where the electric transformation units of four of the provisioning modules 106 are a combination of DC/DC buck-boost converter and DC/AC bidirectional inverter, while the electric transformation units of two of the provisioning modules 106 are composed of DC/DC buck-boost converters and battery chargers.

In FIG. 2C, the electric provisioning system 100 is depicted as not being connected to any electrical equipment. In this functional representation, the electric provisioning system 100 comprises six provisioning modules 106. The electric transformation units of four of the provisioning modules 106 are a combination of DC/DC converters and DC/AC bidirectional inverters, while the electric transformation units of two of the provisioning modules 106 are a combination of DC/DC converters.

In FIG. 2D, the electric provisioning system 100 is illustrated as being connected to the AC network 200, one of several batteries 202 and an electric car 206. In this functional representation, the electric provisioning system 100 comprises five provisioning modules 106. Two of the provisioning modules 106 are a combination of DC/DC buck-boost converter and DC/DC bidirectional converter battery charger, one provisioning module 106 is a combination of an DC/DC buck-boost converter and a DC/AC bidirectional inverter, while two of the provisioning modules 106 are composed of an EV charger and a DC/AC bidirectional inverter.

Finally, in FIG. 2E, the electric provisioning system 100 is illustrated as being connected to the AC network 200, the battery bank 202, solar panels 204, a generator 208 and a grid network 210. In this functional representation, the electric provisioning system 100 comprises five provisioning modules 106. Two of the provisioning modules 106 are a combination of DC/DC bidirectional converter and battery charger, and three provisioning modules 106 are a combination of an DC/DC bidirectional converter and DC/AC bidirectional inverter.

FIGS. 2A-2E depict examples of the flexibility of the present electric provisioning system 100. The present electric provisioning system 100 thus accommodates electric provisioning of various combinations of electrical equipments, by inserting provisioning modules 106 each comprising at least two electric transforming units to allow provisioning to the electrical equipments connected to the electric provisioning system 100 through at least one high voltage DC backplane 108. One of the electric transforming unit of each provisioning module 106 may be detachable from the provisioning module 106.

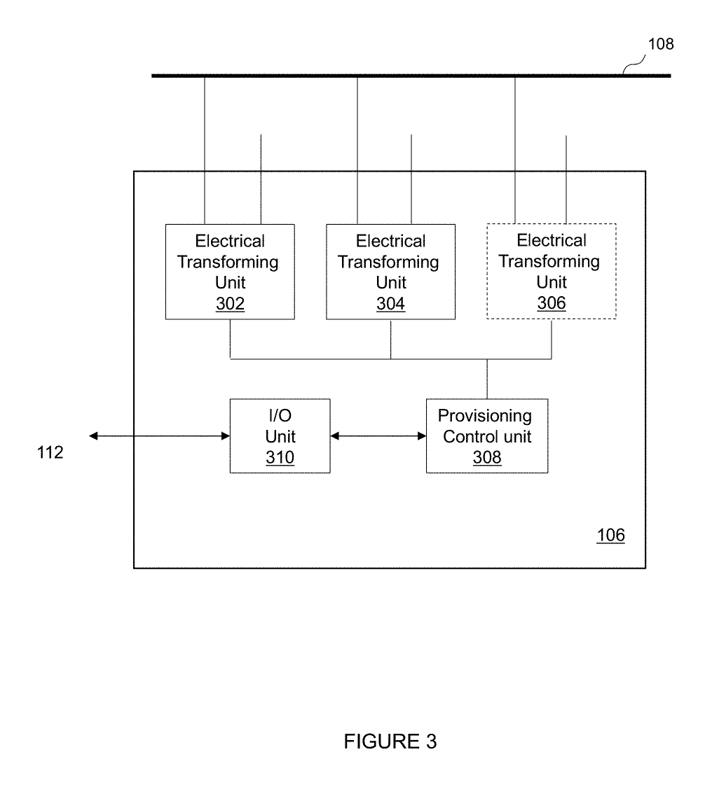

Reference is now additionally made to FIG. 3, which depicts a diagram of the provisioning module 106. The provisioning module 106 comprises at least two electrical transforming units 302 and 304. Depending on the energy requirements and types of energy sources to be concurrently managed, the provisioning module 106 could comprise more than two electrical transforming units 302 and 304. Each electrical transforming unit 302 and 304 is electrically connected to the high voltage DC backplane 108 by means of pins on the back of the provisioning module 106. Each electrical transforming unit 302 and 304 is also connected to one of the other sub-network electric planes 114, 116 or 118. The electric transforming units 302, 304 and 306 are controlled by a provisioning control unit 308. The provisioning control unit 308 receives messages from the control unit 110 through the communication interface 112 and the input/output unit 310. The messages are analyzed and processed by the provisioning control unit 308. The messages received by the provisioning control unit 308 may comprise any of the following: status request, measurement request, version request, voltage information, current information, phase information, synchronization request, actuation request, deactivation request, etc. The provisioning control unit 308 performs measurements, controls the electrical transforming units 302, 304 and 306 based on the internal functionalities programmed or code stored and/or the messages received. The provisioning control unit 308 comprises at least one of the following: a microprocessor, a Digital Signal Processor also known as a DSP, a logic circuit such as for example Field Programmable Gate Array (FPGA), a digital control circuit, and an analog control circuit. Some of the components of the provisioning control unit 308 may be co-located within a separate electrical unit in the provisioning module 106, while other components (such as the analog control circuit(s)) of the provisioning control unit 308 are co-located with the electric transforming units of the provisioning module 106.

The provisioning control unit 308 may participate in ensuring that the high voltage DC backplane 108 is stable and constant. In order to ensure stability of the high voltage DC backplane 108, the provisioning control unit 308 receives measurements of the voltage and current inputted and outputted by the electric transforming units 302, 304, and adjusts the high voltage DC generated by the electrical transforming units 302, 304 by determining whether the conversion factor of the electrical transforming units 302, 304 requires adjustment, calculates the required adjustment, and applies the required conversion factor to stabilize the high voltage DC backplane 108. Typically, the conversion factors are determined by the analog control circuits co-located with the electric transforming units 302 and 304.

When one of the electrical transforming units 302 and 304 is connected to one or several solar panels through a sub-network electric bus, the provisioning control unit 308 extracts the maximum electricity from the solar panel(s) by means of a Maximum Power Point Tracking algorithm executed by a processor of the provisioning control unit 308, unless otherwise instructed by the control unit 110.

Although not shown on FIG. 3, the provisioning module 106 further comprises connectors, isolators as known in the art, to ensure proper and safe electric connection of the electric transforming units 302, 304 to the high voltage DC backplane 108 and the other electric planes 114, 116 or 118 as appropriate. Furthermore, the provisioning module 106 could further include a securing mechanism to ensure solid engagement of the provisioning module 106 in the slot 104 of the housing 102, and an ejection mechanism to facilitate ejection of the provisioning module 106 when engaged in the slot 104 of the housing 102. The engagement mechanism and ejection mechanism are not depicted on the Figures as such mechanisms are well known in the field of hot-pluggable and hot-swappable electric components.

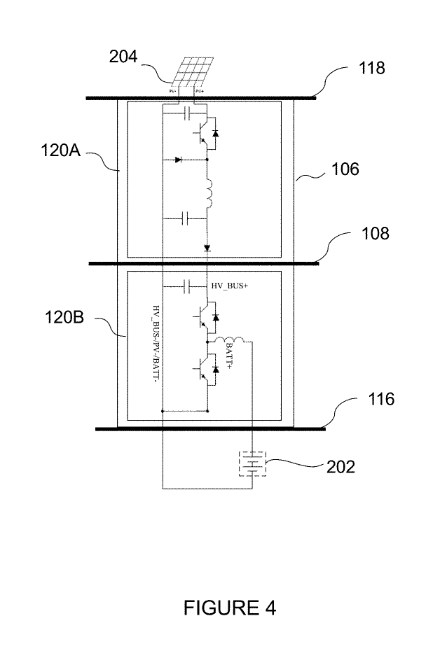

Reference is now further made to FIG. 4, which illustrates a partial electric circuit of a provisioning module 106 in which one of the two electric transforming units is a DC/DC buck converter 120A, connected to the renewable energy source 204 through the renewable energy sub-network electric plane 118 on one side and to the high voltage DC backplane 108 on the other side, and the other one of the two electric transforming units is a DC/DC bidirectional converter 120B, connecting on one end to the high voltage DC backplane 108 and to a battery bank 202 through the DC sub-network electric plane 116 on another end. In this configuration of provisioning module 106, the voltage of the electricity generated by the renewable energy source 204 is lowered to the voltage of the high voltage DC energy which is injected into the high voltage DC backplane 108. The second DC/DC bidirectional converter 120B uses some of the high voltage DC energy from the high voltage DC backplane 108 and converts the high voltage DC energy into lower voltage DC energy (48V for example) to be stored in the battery bank 202 through the DC sub-network electric plane 116. Furthermore, in this configuration of provisioning module 106, the electricity stored in the battery bank 202 can be accessed and provided to the high voltage DC backplane 108 through the DC sub-network electric plane 116 and the DC/DC bidirectional converter 120B.

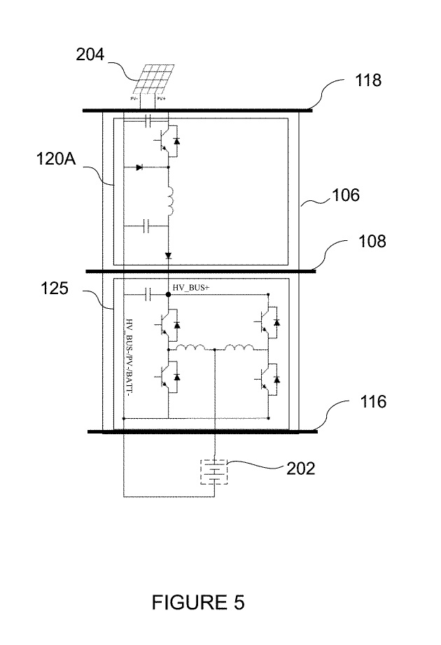

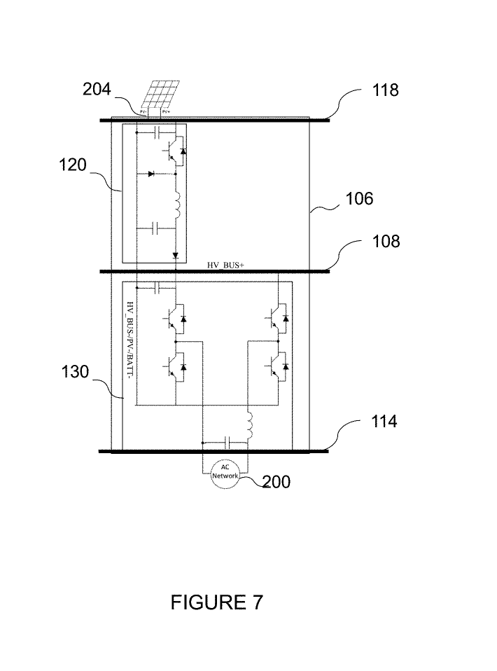

In the case of DC/DC battery converter of FIG. 4, a parallelisation of two DC to DC bidirectional converters within the provisional transformation sub circuit would double the total number of field effect transistors and passive components FIG. 5 and match in quantity of components the inverter provisional transformation sub circuit based on an H-Bridge configuration of FIG. 7. It is therefore possible to layer a similar or identical topology to both provisional transformation sub circuit and also use the same components for both topologies. Some jumpers on the printed circuit board can bring the flexibility of choosing between a DC/DC battery charger converter or an inverter configuration while keeping the same topology and components. These similarities would allow the electric transforming units of the provisioning module 106 to be transformed into other types of electric transforming units with an easy modification, especially when installed in a remote location.

Referring concurrently to FIGS. 3 and 4, in this configuration of provisioning module 106, the provisioning control unit 308 keeps the power constant by ensuring that the current flowing through the DC/DC bidirectional converter 120B is higher than the current flowing through the high voltage DC backplane 108. Thus this configuration of provisioning module 106 benefits from having the DC/DC buck converter 120A and the DC/DC bidirectional converter 120B driven by the provisioning control unit 308, and sharing the high voltage DC backplane 108. The circuits of the DC/DC buck converter 120A and the DC/DC bidirectional converter 120B being independent, by having separate electric components, improves resilience to unbalance of current when switching due to high loads.

Reference is now made to FIG. 5, which illustrates another example of partial electric circuit of provisioning module 106. In this example, one of the electric transforming units of the provisioning module 106 is a DC/DC buck converter 120A connected to the renewable energy source 204 through a renewable energy sub-network electric plane 118 on one side and to the high voltage DC backplane 108 on the other side, and the other electric transforming unit is a dual DC/DC bidirectional converter 125, connected on one end to the high voltage DC backplane 108 and to another end to a battery bank 202 through the DC sub-network electric plane 116. The dual DC/DC bidirectional converter 125 is composed of two DC/DC bidirectional converters 1208 placed in parallel, sharing current while using distinct conversion components such as coils and field effect transistors. In this configuration of provisioning module 106, the voltage of the electricity generated by the renewable energy source 204 is lowered to the voltage of the high voltage DC energy which is injected into the high voltage DC backplane 108. The dual DC/DC bidirectional converter 125 uses some of the high voltage DC energy from the high voltage DC backplane 108 and converts the high voltage DC energy into lower voltage DC energy (48V for example) to be stored in the battery bank 202 through the DC sub-network electric plane 116. Furthermore, in this configuration of provisioning module 106, the electricity stored in the battery bank 202 can be accessed and provided to the high voltage DC backplane 108 through the DC sub-network electric plane 116 and the dual DC/DC bidirectional converter 125.

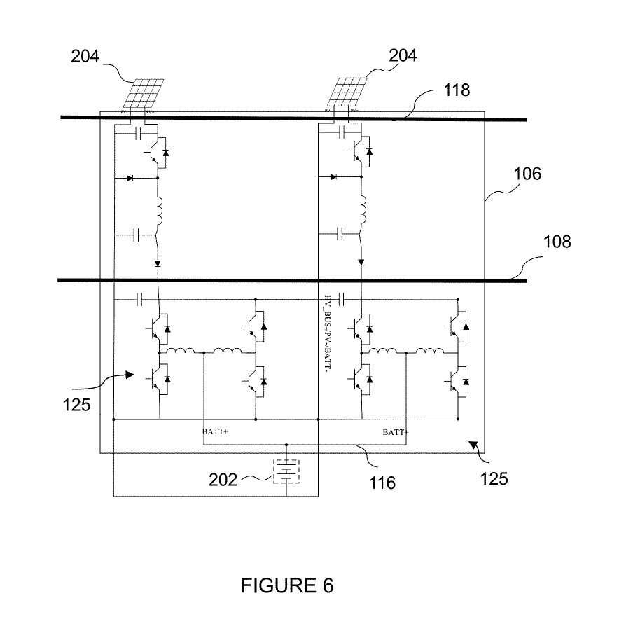

Reference is now made to FIG. 6, which illustrates another example of a partial electric circuit of provisioning module 106. In this example, one of the electric transforming units of the provisioning module 106 is a parallel double bidirectional DC/DC bidirectional converters 120A connected to the renewable energy sub-network electric plane 118 on one side and to the high voltage DC backplane 108 on the other side, and the other electric transforming unit is a dual DC/DC bidirectional converters 125, connecting the high voltage DC backplane 108 to the battery bank 202. The dual DC/DC bidirectional converters 125 are connected in parallel to provide a dual battery charger channel with higher power density. In this configuration of provisioning module 106, the electricity generated by the renewable energy source 204 is lowered to correspond to the voltage of the high voltage DC energy which is injected into the high voltage DC backplane 108. The dual DC/DC bidirectional converters 125 use some of the high voltage DC energy from the high voltage DC backplane 108 and convert the high voltage DC energy into lower voltage DC energy (48V for example) to be stored in the battery bank 202. Furthermore, in this configuration of provisioning module 106, the electricity stored in the battery bank 202 can be accessed and provided to the high voltage DC backplane 108 through the DC sub-network electric plane 116 and the dual DC/DC bidirectional converters 125.

Reference is now made to FIG. 7, which illustrates another example of partial electric circuit of provisioning module. In this example, one of the electric transforming units of the provisioning module 106 is a DC/DC bidirectional converter 120 connected to the renewable energy sub-network electric plane 118 on one side and to the high voltage DC backplane 108 on the other side, and the other electric transforming unit of the provisioning module 106 is a DC/AC bidirectional inverter connected to the high voltage DC backplane 108 on one side and to the AC sub-network electric plane 114 on the other side. In this configuration of provisioning module 106, the voltage of the electricity generated by the renewable energy source 204 is lowered into high 48 voltage DC energy which is injected into the high voltage DC backplane 108. The DC/AC bidirectional inverter 130 uses some of the high voltage DC energy from the high voltage DC backplane 108 and converts the high voltage DC energy into AC energy to be provided to the AC network 200 through the AC sub-network electric plane 114. Furthermore, in this configuration of provisioning module 106, the electricity in the AC network 200 can be accessed and provided to the high voltage DC backplane 108 through the AC sub-network electric plane 114 and the dual DC/AC bidirectional inverter 130.

To control the electric provisioning of the electrical equipments connected thereto, the provisioning system 100 further comprises a control unit 110. The control unit 110 controls either directly (through instructions) or indirectly (by sending operating parameters to be met in messages) operation of the provisioning modules 106, and indirectly the electric transforming units of each provisioning module 106. The control unit 110 further manages the electricity stored to, or consumed by, the various electrical equipments electrically connected to the electric provisioning system 100. The control unit 110 is inserted in any slot 104 of the housing 102. The control unit 110 generates control messages comprising operating parameters for the provisioning modules 106. The control unit 110 includes memory and at least one processor (such as for example a digital signal processor (DSP) for executing instructions. Furthermore, as shown on FIG. 2E, the control unit 110 may further communicate with one or several electrical equipments and/or the grid network 210 to optimize the provisioning of electric energy therewith. The control unit 110 may further comprise a display (not shown) for providing instructions to a user of the electric provisioning system 100 when inserting or removing the provisioning modules 106. The display further provides visual confirmation of the operation status of the electric provisioning system 100, the provisioning modules 106 inserted therein, the electric transforming units and the electrical equipments connected to the electric provisioning system 100. In addition, the control unit 110 further comprises an input/ouput unit to communicate wirelessly with an electronic device either in close proximity with the electric provisioning system 100, or through a wireless hotspot and the Internet to a remote electronic device. The control unit 110 may further be accessed remotely through its input/output unit to extract operating status, verify proper functioning, and perform verifications and tests remotely to ensure proper functioning of the electric provisioning system 100, the provisioning modules 106, the electric transforming units and the electrical equipments connected thereto.

The control unit 110 is further adapted for communicating independently with a grid network operation system through its input/output unit. For doing so, the control unit 110 is further provided with a unique identifier such as an IP address. The control unit 110 may receive from the grid network operation system a request for providing electricity to the grid network. Alternately, the control unit 110 may receive offers from the grid network operation system on electricity currently available at a better rate, or financial offers for buying electricity from the electric provisioning system 100, or make offers to the grid such as electrical signal correction, reactive power injection, etc. The control unit 110 first determines whether the electric provisioning system 100 has exceeding electricity which could be provided to the grid network. However, the first priority of the control unit 110 is to ensure that the electrical needs of the electric provisioning system 100 are met and that all battery, battery banks and electric car are sufficiently charged before providing or selling exceeding electricity generated by the electric provisioning system 100 to the grid network. As the exceeding electricity generated by the electric provisioning system 100 and provided to the grid network is AC, or the electricity purchased from the grid network by the electric provisioning system 100 is AC, the control unit 110 must ensure that the electricity provided/purchased is synchronized with the electricity present on the grid network. The control unit 110 is thus further responsible to synchronizing the AC provided to the grid network with the electricity on the grid network, before actuating relays (not shown) as known in the art for allowing connection of the electric provisioning system 100 to the grid network.

The control unit 110 communicates with the provisioning control unit 308 of the provisioning modules 106 and the electric equipments through a communication interface 112. The communication interface 112 may be realized by any means known in the art, such as wirelessly, by means of electrical wire, by means of a communications bus, or by means of optic fiber. Furthermore, the control unit 110 communicates with the provisioning modules 106 through the communication interface 112 using any known protocol such as Ethernet, Wi-Fi, Modbus, etc. In a particular embodiment, the communication interface 112 is a plurality of communication buses provided in the housing 102 where each of the provisioning modules 106 are hot-pluggable to one of the communication bus. At least one of the communication buses is accessible to each one of the plurality of slots.

The control unit 110 is further responsible for advising users of the electric provisioning system 100 of the best configuration or placement of provisioning modules 106, and more particularly the electric transforming units 302, 304, along the high voltage DC backplane 108 (and 108′ if two high voltage DC backplanes are used). As the electricity between the electric transforming units 302, 304 of each provisioning module 106 travels on the high voltage DC backplane 108 (or on both high voltage DC backplane 108 and 108′), the control unit 110 further determines the optimal positioning of the electric transforming units 302, 304 based on current and voltage needs. For example, to avoid unbalanced electric currents between the electric transforming units 302, 304 of adjacent or subsequent provisioning modules 106, the control unit 110 recommends to a user of the electric provisioning system 100 the provisioning modules 106 based on the electricity currently transported on the high voltage DC backplane 108, and the electric requirements of the electric transforming units 302, 304 of the provisioning module 106 to be inserted. For doing so, the control unit 110 may independently measure the current and voltage on the high voltage DC backplane 108, and request measured current and voltage values from each provisioning module 106 for each electric transforming units 302, 304. Based on the measured current and voltage of the high voltage DC backplane 108, and measured current and voltage values measured by the provisioning control unit 310 of each provisioning module 106, the control unit 110 is capable of detecting unbalanced current flow, and suggest to the user of the electric provisioning system 100 to move some of the provisioning modules 106 along the high voltage DC backplane 108 to reduce current imbalance on the high voltage DC backplane 108.

The control unit 110 communicates with the user of the electric provisioning system 100 either through a display located on the housing 102, or wirelessly through an application which can be accessed through an electronic device such as a computer, a tablet, a mobile phone, etc. The control unit 110 further generates alarms when abnormal situations are detected in the electric provisioning system 100. Examples of abnormal situations include: reduced performances of the battery or battery banks, insufficient charge of the battery or battery banks, increased electric demand on the AC sub-network electric plan 114, or on the DC sub-network electric plane 116.

### Charging of an Electric Car

Referring now to FIGS. 2D, 3, 4 and 7, the fast charging of an electric vehicle 206 using DC electricity is achieved and controlled by the present scalable provisioning electric system instructing one or several of the provisioning modules 106 which contain a DC/DC bidirectional converter, such as 120 or 120A to draw power from the high voltage DC backplane 108 and convert the drawn high voltage electricity into a voltage and current supported as per required by a battery management system (BMS) 307 of the electric vehicle 306. In this application, instead of instructing the DC/DC bidirectional converter 120 or 120A of one or multiple provisioning modules 106 to step down the voltage of the electric energy extracted from the high voltage DC backplane 108, the control unit 110 instructs the DC/DC bidirectional converter 120 or 120A to convert the extracted high voltage DC electricity to a voltage corresponding to the charging parameters of the battery management system 307 of the electric vehicle 206.

Fast charging the electric vehicle 206 with high voltage DC electricity is a difficult task to perform from a commercial or residential installation as the electric power available for charging the battery 308 of the electric vehicle 206 is quite frequently limited by the capacity of the electrical distribution panel or a breaker. By parallelizing the DC/DC bidirectional converters 120 or 120A of multiple provisioning modules 106 and controlling the multiple provisioning modules 106 by the control unit 110 as described herein, it is possible to provision larger amount of electric power from the various electrical equipments connected thereto to charge the electric vehicle battery 308.

### Generator

Referring now more particularly to FIGS. 2E, 3, the scalable electric provisioning system 100 further interacts with a generator 208. The generator 208 is connected to the AC sub-network electric plane 114, through an electric insulation circuit, and is equipped with an automatic start/stop controlled by the control unit 110. The control unit 110 instructs the actuation and interruption of the generator 208. When actuated, the control unit 110 synchronizes the AC electricity on the AC sub-network electric plane 114 and the electricity produced by the generator 208 by sending control messages to the DC/AC inverters of the corresponding provisioning modules 106 electrically feeding from the AC sub-network electric plane 114. When the AC electricity on the AC sub-network electric plane 114 and the electricity produced by the generator 208 can be safely synchronized, the control unit 110 instructs the relays (not shown) at the generator 208 or at the electric provisioning system 100 to provide the AC electricity generated by the generator 208 to be injected to the AC sub-network electric plane 114. The AC electricity produced by the generator 208 then becomes available to the provisioning modules 106 with electric transforming units connected to the AC sub-network electric plane 114. To prevent any electric surge on the provisioning modules 106 with electric transforming units connected to the AC sub-network electric plane 114, every electric transforming unit connected to the AC sub-network electric plane 114 may further be provided with an insulation circuit, limiting the variations of current, voltage and phase which can be injected in the provisioning modules 106 with electric transforming units connected to the AC sub-network electric plane.

When the scalable provisioning electric system 100 determines that the electricity currently available on the high voltage DC backplane 108 is insufficient, the control unit 110 may further actuate the generator 208, and waits for the AC electricity generated by the generator 208 to be synchronized with the AC electricity available on the AC sub-network electric plane 114, and then provide the AC electricity produced by the generator 208 to the AC sub-network electric plane 114 as previously described. The control unit 110 then instructs one or several of the provisioning modules 106 which have electric transforming units connected to the AC sub-network electric plane 114 to convert the AC electricity available on the AC sub-network electric plane 114 into high voltage DC provided to the high voltage DC backplane 108.

Interacting with the Grid

When some conditions are met such as for example renewable energy is abundant, the battery and battery banks are at full charge, and the high voltage DC backplane 108 is at full power (current and voltage), the control unit 110 may determine that it is advantageous financially to redirect the exceeding renewable electrical energy to the grid network 210. Reference is made additionally to FIG. 2E, where the control unit 110 controls one of the provisioning module 106 which includes a DC/AC bidirectional inverter 130 to draw electric energy from the high voltage DC backplane 108, to convert the drawn high voltage DC energy into AC energy provided to the AC sub-network electric plane 114. The AC sub-network electric plane 114, and then to the AC network 200. As previously discussed with the generator 208, the AC electricity on the AC sub-network electric plane 114 is first synchronized with the electricity from the grid network 210, so as to avoid issues related for example to reactive power. Furthermore, as previously discussed with the generator 208, electric insulation is provided between the AC sub-network electric plane 114 and the grid network 210, as well as relays (not shown), as known in the art to connect two distinct electric networks, i.e. the AC sub-network electric plane 114 and the grid network 210. When the control unit 110 determines that it is less interesting from an electric power standpoint or a financial standpoint to provide AC electric energy to the grid network 210, the control unit 110 instructs the DC/AC bidirectional inverter to gradually reduce drawing of electric energy from the high voltage DC backplane 108.

### Split Phase

Reference is now more particularly made to FIGS. 2B, 2C and 3. The scalable provisioning electric system 100 is also adapted for providing split phase AC electricity, i.e. two AC sub-network electric planes 114A and 114B sharing a common neutral for providing AC electricity with opposite phases. For doing so, two different embodiments are possible.

In the first embodiment, the electronic provisioning system 100 comprises two independent high voltage DC backplanes 108 and 108′ as shown on FIG. 2C. The two independent high voltage DC backplanes 108 and 108′ are at similar voltage and current. Some of the provisioning modules 106 are directly electrically connected to the first high voltage DC backplane 108 and to the first AC sub-network electric plane 114, while the other provisioning modules 106 are directly electrically connected to the second high voltage DC backplane 108′ and to the second AC sub-network electric plane 114′. The phases of the first AC sub-network electric plane 114 and of the second AC sub-network electric planes 114′ are at 180°. To ensure an acceptable electric power balance of the first and second AC sub-network electric planes 114 and 114′ and first and second high voltage DC backplanes 108 and 108′, the total electric requirements (current and voltage) of the provisioning modules 106 connected to the first high voltage DC backplane 108 is similar to the total electric requirements (current and voltage) of the provisioning modules 106 connected to the second high voltage DC backplane 108′. Having two independent high voltage DC backplanes 108 and 108′ and two AC sub-network electric planes 114 and 114′ isolate the first AC sub-network electric plane 114 and first high voltage DC backplane 108 from the second AC sub-network electric plane 114′ and second high voltage DC backplane 108′.

In the second embodiment, instead of having the two independent high voltage DC backplanes 108 and 108′ sharing a neutral, each electric transforming unit 302, 304 of each provisioning module 106 that are DC/DC is provided with an electric insulation.

Although the present disclosure has been described hereinabove by way of non-restrictive, illustrative embodiments thereof, these embodiments may be modified at will within the scope of the appended claims without departing from the spirit and nature of the present disclosure.

What is claimed is:

1. A scalable electric provisioning system comprising:
a housing defining a plurality of slots;
a high voltage direct current (DC) backplane, the high voltage DC backplane being located within the housing and being electrically accessible through each one of the plurality of slots;
a communication interface;
at least one provisioning module inserted into one of the slots, the at least one provisioning module comprising two electric transforming sub-units selected from any of the following: a DC/DC converter, a DC/DC buck converter, a DC/DC buck-boost converter, a DC/DC bidirectional converter, an electric inverter, a bidirectional electric inverter, an AC/DC three phase inverter, and a battery charger, the two electric transforming sub-units being directly electrically connected to the high voltage DC backplane,
a control unit for controlling operation of the at least one provisioning unit, the control unit generating control messages comprising operating parameters for the at least one provisioning unit, the control messages being delivered through the communication interface.

2. The scalable electric provisioning system of claim 1, further comprising an AC sub-network electric plane, at least one of the electric transforming sub-unit being also connected to the AC sub-network electric plane.

3. The scalable electric provisioning system of claim 1, further comprising a DC sub-network electric plane for connecting at least one of the electric transforming sub-unit to a battery bank.

4. The scalable electric provisioning system of claim 1, further comprising two AC sub-network electric planes, the two AC sub-network electric planes being at opposing electric phases.

5. The scalable electric provisioning system of claim 1, wherein one of the electric transforming units is also connected to a renewable source of energy.

6. The scalable electric provisioning system of claim 5, wherein the one of the electric transforming units is connected to a solar panel array.

7. The scalable electric provisioning system of claim 1, wherein each provisioning module further comprises a provisioning control unit for receiving and executing the control messages received from the control unit.

8. The scalable electric provisioning system of claim 7, wherein each provisioning control unit further generates report messages sent to the control unit.

9. The scalable electric provisioning system of claim 1, wherein each electric transforming unit further comprises an electric insulation circuit.

10. The scalable electric provisioning system of claim 1, wherein the control unit further controls operation of at least one of the following: a car charger and a generator.

11. The scalable electric provisioning system of claim 1, wherein the control unit further controls exchange of AC electricity with a grid network.

12. The scalable electric provisioning system of claim 1, wherein the communication interface comprises a communication bus and each provisioning module is connected to the communication bus upon insertion in one of the slots of the housing.
